(19) United States
(12) Patent Application Publication
(10) Pub. No.: US 2009/0231004 A1
(43) Pub. Date: Sep. 17, 2009

(54) DIGITAL CYCLE CONTROLLED OSCILLATOR AND METHOD FOR CONTROLLING THE SAME

(75) Inventor: Hsiang-Hui Chang, Taipei Hsien (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK INC., Hsin-Chu (TW)

(21) Appl. No.: 12/047,389

(22) Filed: Mar. 13, 2008

(51) Int. Cl. H03L 7/00

(52) U.S. Cl. 327/160; 327/161

(57) ABSTRACT

An oscillator is disclosed. The oscillator comprises a cycle controller and a re-cycle delay line module. The cycle controller generates a cycle control signal. The re-cycle delay line module produces a periodic signal. The re-cycling delay line module performs a re-cycling operation. The number of re-cycling in the re-cycling operation is determined based on the cycle control signal.

### BACKGROUND OF THE INVENTION

1. Field of the Invention

The invention relates to an oscillator, and more particularly to a digital controlled oscillator.

2. Description of the Related Art

With advances in deep-submicron technologies, the demand for high-performance and short time-to-market integrated circuits has dramatically grown recently. Scalable microprocessor and graphic-processor systems could cost-effectively port to advanced technologies to increase the clocking rate, lower the power dissipations, and reduce design turn-around time. The synchronization among IC modules is an important issue. Thus, considerable efforts have been focused on high-performance digital interface circuits to communicate with these digital systems. Phase-locked loops (PLLs) have been widely used in many high-speed microprocessors and memories. The traditional analog PLL generally has better jitter and skew performances, but it is process-dependent and needs a long design time. Conversely, the digital PLL can be migrated over different processes. Moreover, with benefits from scaling CMOS technologies, the digital PLL has a lower supply voltage and the potential for good power management. To apply a digital PLL in various clock-generation circuits or phase-alignment circuits, the operating frequency range should be as large as possible to meet different product's specifications. Furthermore, the wide-range PLL should tolerate wide variations of clock frequency, process, and temperature.

FIG. 1 is a schematic diagram of a conventional DCO (digital-controlled-oscillator). The conventional oscillator 10 comprises a delay line 12 and a phase selector 14. Phase selector 14 controls delay units 121˜12n.

The highest operating frequency of a PLL is limited by the bandwidth of a single delay unit (121-12n) used in the DCO (digital-controlled-oscillator) while the lowest operating frequency is restricted by total delay of the delay line 12. The maximum operating frequency range of this DCO could be expressed as

$$F = \frac{1}{T} \\ {T}_{l} \leq T \leq {C}_{max} * Δ t + {T}_{l} \qquad Eq . ( 1 )$$

where T is the total delay of delay line 12, Tₗ is the intrinsic delay when the value of all control bits are low, and Cmax is the maximum number of delay units 121-12n used in the delay line 12. As indicated from Eq. (1), the operating frequency range trades off the hardware complexity and the timing resolution. One may either increase C or td to extend the operating frequency range. However, the former will increase the hardware complexity and the later will decrease the timing resolution. In order to meet the maximum and the minimum speed requirement at the same time, a conventional digital PLL demands a DCO composed of high-bandwidth delay units 121-12n. However, to realize such a DCO by a reasonable chip area, the tradeoff between bandwidth of a single delay unit and length of the delay line 12 will substantially limit the ratio of maximum to minimum operating frequency.

### BRIEF SUMMARY OF THE INVENTION

According to one embodiment of the present invention, an oscillator is disclosed. The oscillator comprises a cycle controller and a re-cycle delay line module. The cycle controller generates a cycle control signal. The re-cycle delay line module produces a periodic signal. The re-cycling delay line module performs a re-cycling operation. The number of re-cycling in the re-cycling operation is determined based on the cycle control signal.

According to another embodiment of the present invention, an oscillator is disclosed. The oscillator comprises a re-cycle delay line module and a second delay line. The re-cycle delay line module performs a re-cycling operation. The number of re-cycling in the re-cycling operation is determined based on a cycle control signal. The re-cycle delay line module comprises a first delay line.

According to another embodiment of the present invention, a method for producing a periodic signal is disclosed. The method comprises the following steps. A recycling operation is performed on a first close loop of a first delay line when a re-cycling mode is enabled. A second delay line is connected to the first delay line and a second close loop is formed when the re-cycling mode is disabled. The periodic signal is outputted from the second close loop.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a schematic diagram of a conventional oscillator;

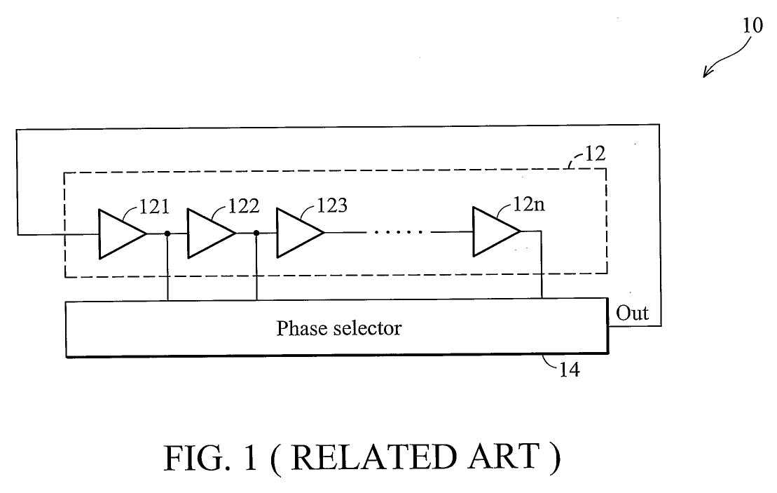

FIG. 2 shows a block diagram of an exemplary DCCO (digital-cycle-controlled oscillator);

FIG. 3 shows an embodiment of a DCCO;

FIG. 4 shows the simulated results when M=5; and

FIG. 5 shows the simulated results when M=100.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

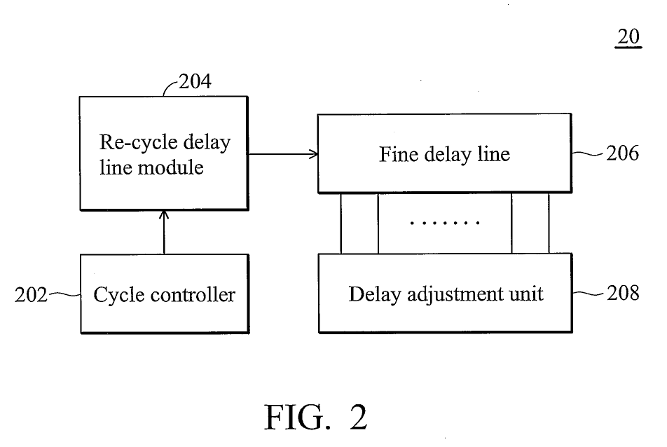

FIG. 2 shows a block diagram of an exemplary DCCO (digital-cycle-controlled oscillator). The DCCO 20 comprises a cycle controller 202, a re-cycle delay line module 204, a fine delay line 206, and a delay adjustment unit 208. The re-cycle delay line module 204 is used to increase the ratio of maximum to minimum operating range of the DCCO 20. The fine delay line 206 is used to fine-tune or make an interpolation of the operating frequency of the DCCO 20. In one embodiment, the fine delay line 206 and the delay adjustment unit 208 can be omitted if a fine resolution is not desired.

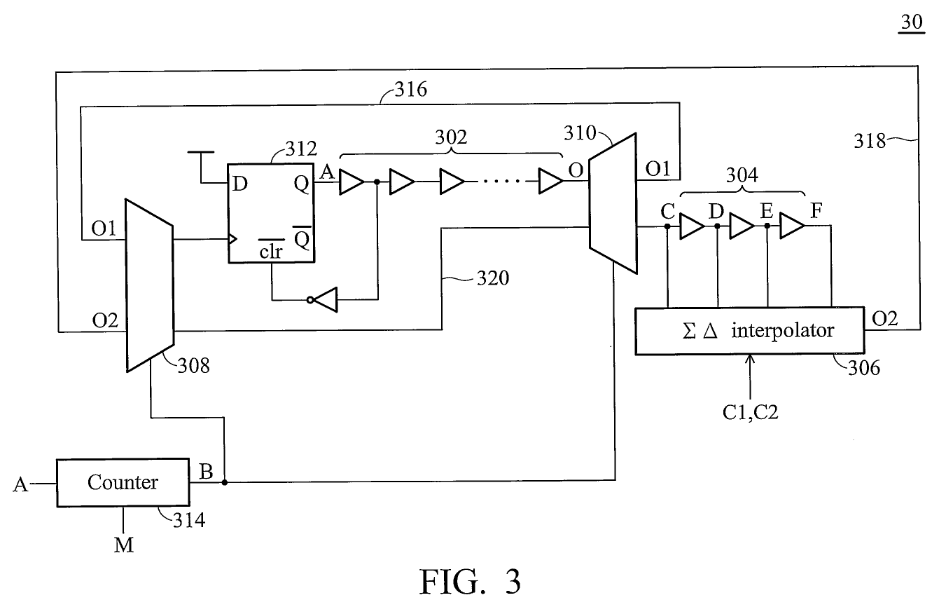

FIG. 3 shows an embodiment of a DCCO. The DCCO 30 is an embodiment of the block diagram of the DCCO 20 shown in FIG. 2. In this embodiment, the re-cycle delay line module 204 (FIG. 2) is implemented by a re-cycle delay line 302, a first selection unit 308, and a second selection unit 310 (FIG. 3). The fine delay line 206 (FIG. 2) is the same as the fine delay line 304 (FIG. 3). The delay adjustment unit 208 (FIG. 2) is implemented by a delta-sigma interpolator 306. The delay unit in the re-cycle delay line 302 can be re-used to increase the operating frequency range with small hardware overhead. The re-use process is a re-cycling operation. The re-cycling operation is performed on a first close loop formed by the re-cycle delay line 302 and the path 316. Thus, the bandwidth of the delay unit in the re-cycle delay line can be as large as possible to achieve the maximum operating frequency requirement while the lowest operating frequency requirement can be accomplished by increasing the times of re-use. The times of re-use are the number of re-cycling. The number of re-cycling is determined by the cycle controller 202. After the re-cycling operation, the re-cycle delay line 302 is connected to the fine delay line 304. The re-cycling delay line 302, the fine delay line 304, and the path 318 form a second close loop. The fine delay line 304 can compensate the residue delay compared with the desired operating period. The interpolator 306 can further increase timing resolution. Output signal of the DCCO 30 is provided on the node O2. The operating frequency range of the proposed DCCO 30 can be expressed by

$$F = \frac{1}{T} \\ {T}_{l} \leq T \leq M * {C}_{max} * Δ t + C 1 * Δ t + C 2 * Δ t + {T}_{l} \\ 0 < C 1 < {C}_{max} \\ 0 < C 2 < 1 \qquad Eq . ( 2 )$$

where T is the total delay of delay line (including the re-cycle delay line 302 and the fine delay line 304), Tₗ is the intrinsic delay when the value of all control bits are low, M is times of re-use, Cₘₐₓ is the number of delay units used in the re-cycle delay line 302, C1 is number of delay units used in the fine delay line 304, and C2 is the interpolating factor. The ratio of the maximum operating frequency range of the proposed DCCO 30 to that of a conventional digital DCO (digital-controlled-oscillator) could be approximated as

$$\frac{M * {C}_{max} * Δ t + C 1 * Δ t + C 2 * Δ t + {T}_{l}}{{C}_{max} * Δ t} \approx M + 1 \qquad Eq . ( 3 )$$

Since the hardware complexity of the controller is proportional to the operating frequency range, the overall hardware complexity of the proposed DCCO 30 could be significantly reduced compared with a conventional digital DCO at a given operating frequency range and timing resolution.

In this embodiment, the first selection unit 308 is implemented by a first multiplexer and the second selection unit 310 is implemented by a second multiplexer. The DCCO 30 can further include a D flip-flop 312. The re-cycle delay includes the delays introduced by two multiplexers (308 and 310), Cmax delay units (302), and one DFF 312. The bandwidth of the delay unit can be designed to be as large as possible to achieve the maximum operating frequency requirement. In this embodiment, the cycle controller 202 (FIG. 2) can be implemented by a counter 314. The counter 314 generates a cycle control signal B. The cycle control signal B controls the multiplexers (308, and 310) to select the signal on nodes O1 or O2 into the re-cycle delay line 302. For example, when B=1, a re-cycle mode is enabled. The signal on the node O1 enters the re-cycle delay line 302, and the node O is connected to the node O1. When B=0, the re-cycle mode is disabled. The signal on the node O2 enters the re-cycle delay line 302 and the node O is connected to be node C. It allows the clock to circulate in the re-cycle delay line 302 according to different operating frequencies. The delay time of the re-cycle delay line 302 could be increased by reusing the delay units rather than cascading extra delay units. The counter 314 sets the optimal cycles of the re-cycle delay line 302. The undesired duty cycle distortion of the delay line 302 may cause the disappearance of the output signal on the node O in a low frequency operation due to mismatches of the driving capability of NMOS and PMOS in the re-cycle delay line 302. To solve the problem, an edge-triggered D flip-flop 312 is placed in the front of the delay line 302 to respond for edge recovery. If a very high output frequency is desired, the signal on the node O2 can directly bypass the re-cycle delay line 302, and only the fine delay line 304 is used. In this situation, the path 320, the path 318, and the fine delay line 304 form a close loop to achieve the maximum output frequency. In this embodiment, the interpolator 306 chooses two successive phases in fine delay line as an interpolating phase according to C1. Then, the interpolating phase is interpolated to generate the final phase according to C2. The control codes, C2, can be further modulated with high speed dithering to improve the timing resolution.

Simulated Results

The simulated conditions are listed as followings:

Δt=2 ns

Cₘₐₓ=4

C1=2

C2=0.25

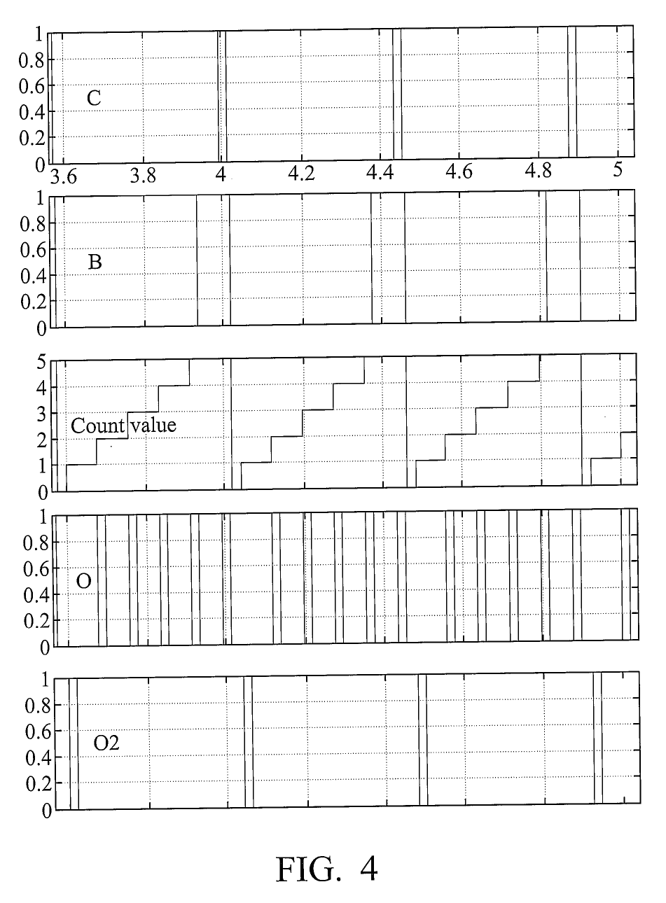

FIG. 4 shows the simulated results when M=5. The delay units in the re-cycle delay line 302 are re-used five times. The total delay time is given by

T=5*4*2 ns+2*2 ns+0.25*2 ns=44.5 ns

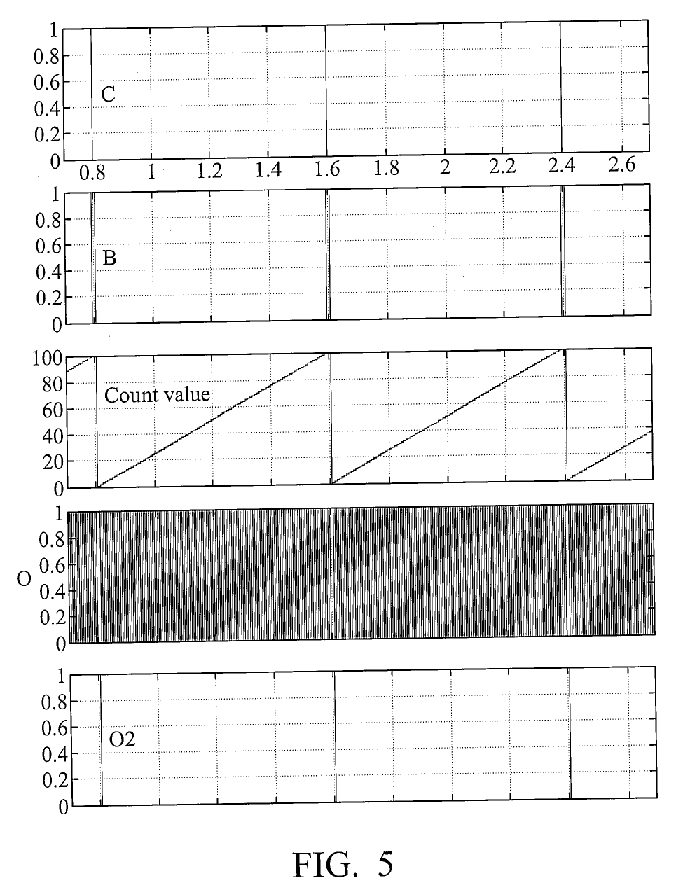

FIG. 5 shows the simulated results when M=100. The delay units in the re-cycle delay line 302 are re-used 100 times. The total delay time is given by

T=100*4*2 ns+2*2 ns+0.25*2 ns=804.5 ns

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An oscillator, comprising:
a cycle controller for generating a cycle control signal; and
a re-cycle delay line module for producing a periodic signal, the re-cycling delay line module performing a re-cycling operation, wherein the number of re-cycling in the re-cycling operation is determined based on the cycle control signal.

2. The oscillator as claimed in claim 1, wherein the cycle controller is a counter.

3. The oscillator as claimed in claim 1, wherein the re-cycle delay line module comprises a first delay line, a first selection unit, and a second selection unit, and the first delay line is controlled by the first and the second selection units to form a first close loop for the re-cycling operation.

4. The oscillator as claimed in claim 3, further comprising a second delay line coupled to the first and the second selection units, the first and the second selection units controlling the first and the second delay line to form a second close loop after the re-cycling operation.

5. The oscillator as claimed in claim 4, further comprising a delay adjustment unit for controlling the second delay line.

6. The oscillator as claimed in claim 3, wherein the re-cycle delay line module further comprises a D flip-flop coupled between the first selection unit and the first delay line.

7. An oscillator, comprising:
a re-cycle delay line module for performing a re-cycling operation, wherein the number of re-cycling in the re-cycling operation is determined based on a cycle control signal, the re-cycle delay line module comprising a first delay line; and
a second delay line coupled to the re-cycle delay line module.

8. The oscillator as claimed in claim 7, further comprising a cycle controller for generating the cycle control signal.

9. The oscillator as claimed in claim 8, wherein the cycle controller is a counter.

10. The oscillator as claimed in claim 7, wherein the re-cycle delay line module further comprises a first selection unit and a second selection unit, and the first delay line is controlled by the first and the second selection units to form a first close loop for the re-cycling operation.

11. The oscillator as claimed in claim 10, wherein the re-cycle delay line module further comprises a D flip-flop coupled between the first selection unit and the first delay line.

12. The oscillator as claimed in claim 10, wherein the first and the second selection units control the first and the second delay lines to form a second close loop after the re-cycling operation.

13. The oscillator as claimed in claim 7, further comprising a delay adjustment unit for controlling the second delay line.

14. A method for producing a periodic signal, the method comprising:
performing a re-cycling operation on a first close loop comprising a first delay line when a re-cycling mode is enabled;
connecting a second delay line to the first delay line and forming a second close loop when the re-cycling mode is disabled; and
outputting the periodic signal from the second close loop.

15. The method as claimed in claim 14, further comprising:
providing a number of re-cycling in the re-cycling operation by a counter.

16. The method as claimed in claim 14, further comprising:
switching between the first close loop and the second close loop by a first and a second selection units.
